(19) United States
(12) Patent Application Publication
(10) Pub. No.: US 2025/0048836 A1
(43) Pub. Date: Feb. 6, 2025

(54) DISPLAY DEVICE

(71) Applicant: Sharp Display Technology Corporation, Kameyama City, Mie (JP)

(72) Inventors: Tadayoshi MIYAMOTO, Kameyama City, Mie (JP); Sohtaroh TANAKA, Kameyama City, Mie (JP); Fumie YASHIRO, Kameyama City, Mie (JP)

(21) Appl. No.: 18/722,590

(22) PCT Filed: Feb. 21, 2022
(86) PCT No.: PCT/JP2022/006944

§ 371 Date: Jun. 21, 2024

(51) Int. Cl. H10K 59/121; H01L 27/12; H10K 59/12

(52) U.S. Cl. CPC H10K 59/1213; H01L 27/1233; H01L 27/1296; H10K 59/1201

(57) ABSTRACT

A display device includes a thin film transistor layer provided with a first thin film transistor and a second thin film transistor. The first thin film transistor includes a first semiconductor layer and a first gate electrode. The second thin film transistor includes a second semiconductor layer and a second gate electrode. The first gate electrode includes a thick film electrode portion and a thin film electrode portion in such a manner as to overlap the thick film electrode portion and protrude from the thick film electrode portion toward at least one side in a channel length direction. The first semiconductor layer is provided with a low-concentration impurity region in such a manner as to overlap a portion of the thin film electrode portion protruding from the thick film electrode portion. A lower conductive layer is provided on a base substrate side of the second semiconductor layer.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. In the organic EL display device, a plurality of thin film transistors (hereinafter also referred to as “TFTs”) are provided for each subpixel being the smallest unit of an image. Well known examples of a semiconductor layer constituting the TFT include a semiconductor layer made of polysilicon having high mobility, and a semiconductor layer made of an oxide semiconductor with a low leakage current such as In—Ga—Zn—O.

For example, PTL 1 discloses a display device having a hybrid structure in which a first TFT using a polysilicon semiconductor and a second TFT using an oxide semiconductor are formed on a substrate.

### CITATION LIST

### Patent Literature

PTL 1: JP 2020-17558 A

### SUMMARY

### Technical Problem

In the organic EL display device having the hybrid structure disclosed in PTL 1, when the TFT using the polysilicon semiconductor is provided as a drive TFT for controlling a drive current of an organic EL element, when the characteristics of the TFT vary, a light emission intensity of the organic EL element greatly changes, so that luminance unevenness, image sticking, or the like may occur to degrade display quality. Here, a TFT using an oxide semiconductor has a property of being more vulnerable to light than the TFT using polysilicon, so that when light is incident on the TFT using the oxide semiconductor in the organic EL display device having the hybrid structure disclosed in PTL 1, characteristics of the TFT may be deteriorated. Thus, in the display device having the hybrid structure, it is necessary to efficiently achieve both stabilization of the characteristics of the TFT using the polysilicon semiconductor and suppression of the deterioration of the characteristics of the TFT using the oxide semiconductor due to the light incidence.

The disclosure has been conceived in view of the above points, and an object thereof in the display device having the hybrid structure is to stabilize characteristics of the TFT using the polysilicon semiconductor and suppress the deterioration of the characteristics of the TFT using the oxide semiconductor due to the light incidence, as efficiently as possible.

### Solution to Problem

In order to achieve the above object, a display device according to the disclosure includes a base substrate and a thin film transistor layer provided on the base substrate, the thin film transistor layer including a first semiconductor film made of polysilicon, a first inorganic insulating film, a first metal film, a second metal film, a second inorganic insulating film, a second semiconductor film made of an oxide semiconductor, a third inorganic insulating film, and a third metal film sequentially layered, in which the thin film transistor layer is provided with a first thin film transistor including a first semiconductor layer formed of the first semiconductor film and a second thin film transistor including a second semiconductor layer formed of the second semiconductor film for each subpixel constituting a display region, the first thin film transistor includes the first semiconductor layer including a first conductor region and a second conductor region defined to be separated from each other and a first channel region defined between the first conductor region and the second conductor region, and a first gate electrode provided on the first semiconductor layer via the first inorganic insulating film and formed of a layered film of the first metal film and the second metal film, the second thin film transistor includes the second semiconductor layer including a third conductor region and a fourth conductor region defined to be separated from each other and a second channel region defined between the third conductor region and the fourth conductor region, and a second gate electrode provided on the second semiconductor layer via the third inorganic insulating film and formed of the third metal film, the first gate electrode includes a thick film electrode portion formed of a thicker one of the first metal film and the second metal film, and a thin film electrode portion formed of a thinner one of the first metal film and the second metal film in such a manner as to overlap the thick film electrode portion and protrude from the thick film electrode portion toward at least one side in a channel length direction, the first semiconductor layer is provided with a low-concentration impurity region having an impurity concentration lower than an impurity concentration of each of the first conductor region and the second conductor region in such a manner as to overlap a portion of the thin film electrode portion protruding from the thick film electrode portion, and a lower conductive layer formed of a thinner one of the first metal film and the second metal film is provided on the base substrate side of the second semiconductor layer in such a manner as to overlap the second channel region.

### Advantageous Effects of Disclosure

According to the disclosure, in a display device having a hybrid structure, characteristics of a TFT using a polysilicon semiconductor can be stabilized and deterioration of the characteristics of the TFT using an oxide semiconductor due to light incidence can be suppressed, as efficiently as possible.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a TFT layer constituting the organic EL display device according to the first embodiment of the disclosure.

FIG. 5 is a cross-sectional view illustrating an organic EL layer included in the organic EL display device according to the first embodiment of the disclosure.

FIG. 6 is a first cross-sectional view illustrating a part of a manufacturing process of the organic EL display device according to the first embodiment of the disclosure.

FIG. 7 is a second cross-sectional view illustrating a part of the manufacturing process of the organic EL display device according to the first embodiment of the disclosure, continuing from FIG. 6.

FIG. 8 is a third cross-sectional view illustrating a part of the manufacturing process of the organic EL display device according to the first embodiment of the disclosure, continuing from FIG. 7.

FIG. 9 is a fourth cross-sectional view illustrating a part of the manufacturing process of the organic EL display device according to the first embodiment of the disclosure, continuing from FIG. 8.

FIG. 10 is a fifth cross-sectional view illustrating a part of the manufacturing process of the organic EL display device according to the first embodiment of the disclosure, continuing from FIG. 9.

FIG. 11 is a six cross-sectional view illustrating a part of the manufacturing process of the organic EL display device according to the first embodiment of the disclosure, continuing from FIG. 10.

FIG. 12 is a seventh cross-sectional view illustrating a part of the manufacturing process of the organic EL display device according to the first embodiment of the disclosure, continuing from FIG. 11.

FIG. 13 is an eighth cross-sectional view illustrating a part of the manufacturing process of the organic EL display device according to the first embodiment of the disclosure, continuing from FIG. 12.

FIG. 14 is a ninth cross-sectional view illustrating a part of the manufacturing process of the organic EL display device according to the first embodiment of the disclosure, continuing from FIG. 13.

FIG. 15 is a tenth cross-sectional view illustrating a part of the manufacturing process of the organic EL display device according to the first embodiment of the disclosure, continuing from FIG. 14.

FIG. 16 is an eleventh cross-sectional view illustrating a part of the manufacturing process of the organic EL display device according to the first embodiment of the disclosure, continuing from FIG. 15.

FIG. 17 is a twelfth cross-sectional view illustrating a part of the manufacturing process of the organic EL display device according to the first embodiment of the disclosure, continuing from FIG. 16.

FIG. 18 is a thirteenth cross-sectional view illustrating a part of the manufacturing process of the organic EL display device according to the first embodiment of the disclosure, continuing from FIG. 17.

FIG. 19 is a fourteenth cross-sectional view illustrating a part of the manufacturing process of the organic EL display device according to the first embodiment of the disclosure, continuing from FIG. 18.

FIG. 20 is a fifteenth cross-sectional view illustrating a part of the manufacturing process of the organic EL display device according to the first embodiment of the disclosure, continuing from FIG. 19.

FIG. 21 is a cross-sectional view of a display region of an organic EL display device according to a second embodiment of the disclosure, and is a view corresponding to FIG. 3.

FIG. 22 is a cross-sectional view of a display region of an organic EL display device according to a third embodiment of the disclosure, and is a view corresponding to FIG. 3.

FIG. 23 is a cross-sectional view of a display region of an organic EL display device according to a fourth embodiment of the disclosure, and is a view corresponding to FIG. 3.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

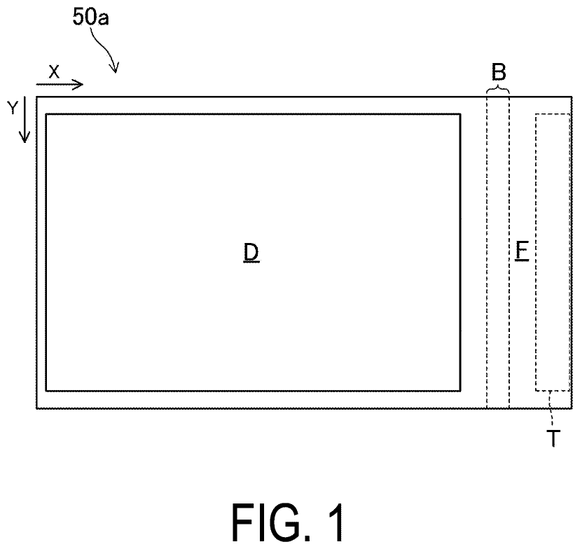

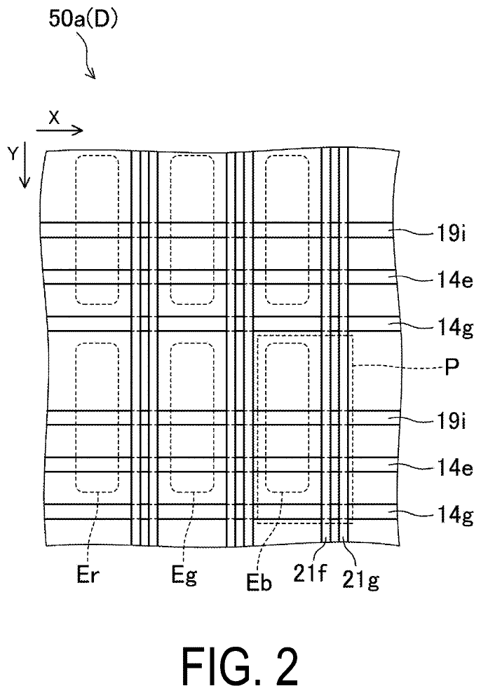

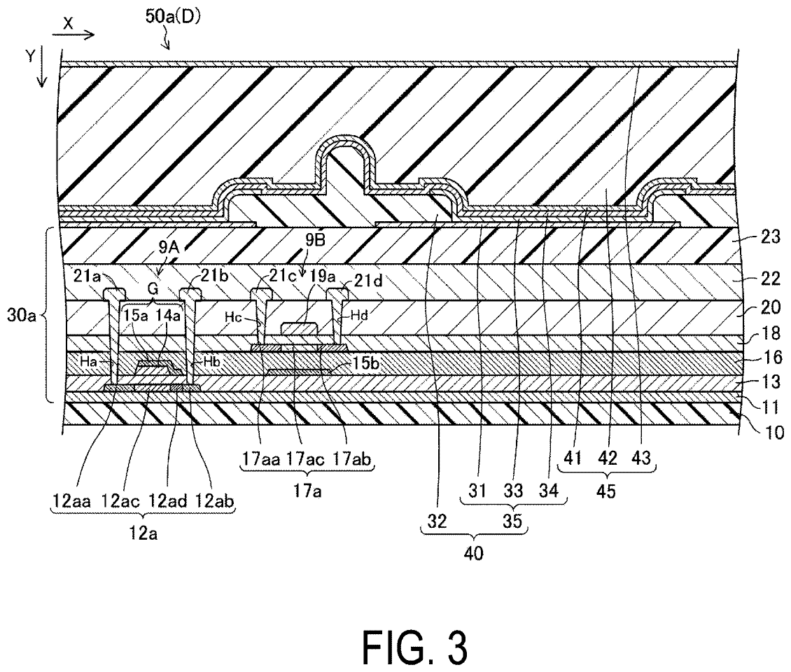

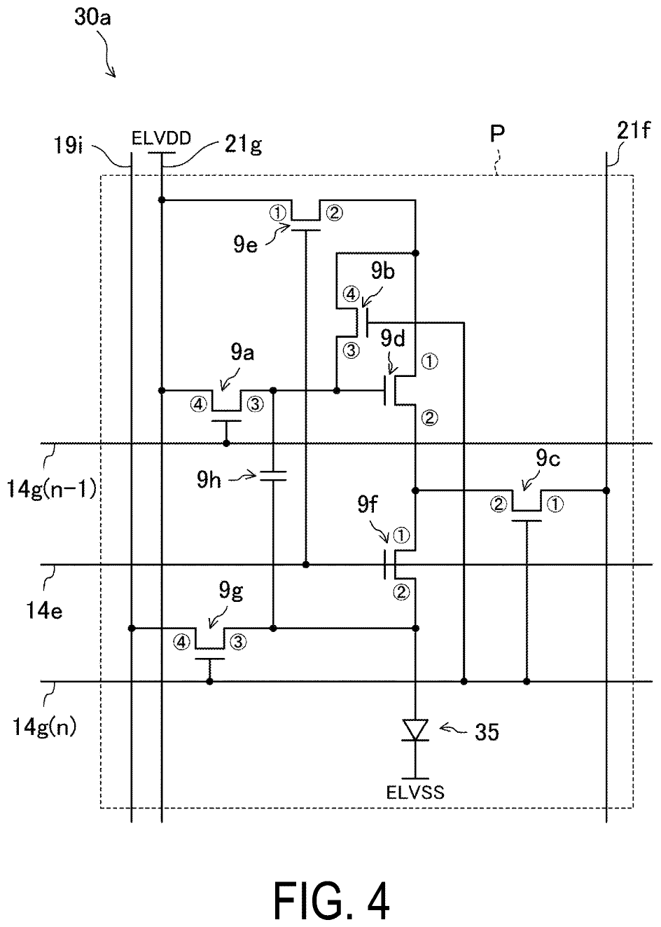

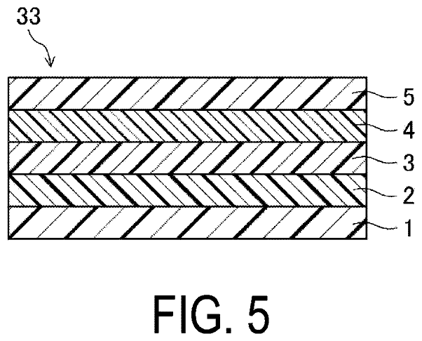

FIGS. 1 to 20 illustrate a first embodiment of a display device according to the disclosure. Note that, in each of the following embodiments, an organic EL display device including an organic EL element layer is exemplified as a display device including a light-emitting element layer. Here, FIG. 1 is a plan view illustrating a schematic configuration of an organic EL display device 50a according to the present embodiment. FIG. 2 and FIG. 3 are a plan view and a cross-sectional view, respectively, of a display region D in the organic EL display device 50a. FIG. 4 is an equivalent circuit diagram of a TFT layer 30a included in the organic EL display device 50a. Additionally, FIG. 5 is a cross-sectional view illustrating an organic EL layer 33 included in the organic EL display device 50a.

As illustrated in FIG. 1, the organic EL display device 50a includes, for example, the display region D provided in a rectangular shape and configured to display an image, and a frame region F provided in a periphery of the display region D. Note that in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a cutout.

As illustrated in FIG. 2, a plurality of subpixels P are arrayed in a matrix shape in the display region D. In addition, in the display region D, for example, a subpixel P including a red light-emitting region Er configured to display a red color, a subpixel P including a green light-emitting region Eg configured to display a green color, and a subpixel P including a blue light-emitting region Eb configured to display a blue color are provided adjacent to one another, as illustrated in FIG. 2. Note that one pixel is configured by, for example, the three adjacent subpixels P including the red light-emitting region Er, the green light-emitting region Eg, and the blue light-emitting region Eb in the display region D.

A terminal portion T is provided at an end portion on a positive side in an X direction of the frame region F in FIG. 1 so as to extend in one direction (Y direction in FIG. 1). Further, as illustrated in FIG. 1, in the frame region F, a bendable bending portion B that can bend, for example, by 180° (in a U-shape) with the Y direction in the drawing as a bending axis is provided between the display region D and the terminal portion T so as to extend in one direction (the Y direction in the drawing).

As illustrated in FIG. 3, the organic EL display device 50a includes a resin substrate 10 provided as a base substrate, the TFT layer 30a provided on the resin substrate 10, an organic EL element layer 40 provided as a light-emitting element layer on the TFT layer 30a, and a sealing film 45 provided on the organic EL element layer 40. The resin substrate 10 is made, for example, of an organic resin material such as a polyimide resin or the like.

As illustrated in FIG. 3, the TFT layer 30a includes a base coat film 11 provided on the resin substrate 10, four first TFTs 9A, three second TFTs 9B, and one capacitor 9h (see FIG. 4) provided on the base coat film 11 for each subpixel P, and a protective insulating film 22 and a flattening film 23 sequentially provided on all of the first TFTs 9A, the second TFTs 9B, and the capacitors 9h. Here, as illustrated in FIG. 2, in the TFT layer 30a, a plurality of gate lines 14g are provided to extend parallel to each other in the X direction in the drawing. As illustrated in FIG. 2, in the TFT layer 30a, a plurality of light emission control lines 14e are provided to extend parallel to each other in the X direction in the drawing. As illustrated in FIG. 2, in the TFT layer 30a, a plurality of second initialization power source lines 19i are provided to extend parallel to each other in the X direction in the drawing. As illustrated in FIG. 2, each light emission control line 14e is provided adjacent to each gate line 14g and also adjacent to each second initialization power source line 19i. As illustrated in FIG. 2, in the TFT layer 30a, a plurality of source lines 21f are provided to extend parallel to each other in the Y direction in the drawing. As illustrated in FIG. 2, in the TFT layer 30a, a plurality of power source lines 21g are provided to extend parallel to each other in the Y direction in the drawing. As illustrated in FIG. 2, each power source line 21g is provided adjacent to each source line 21f.

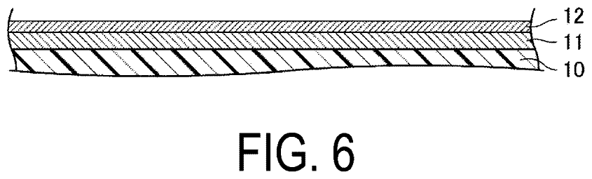

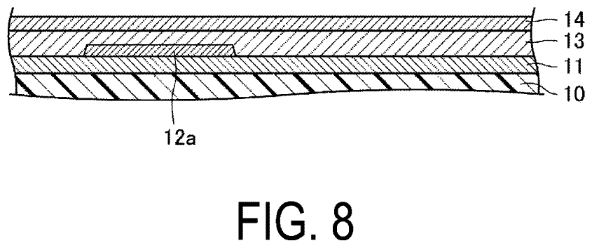

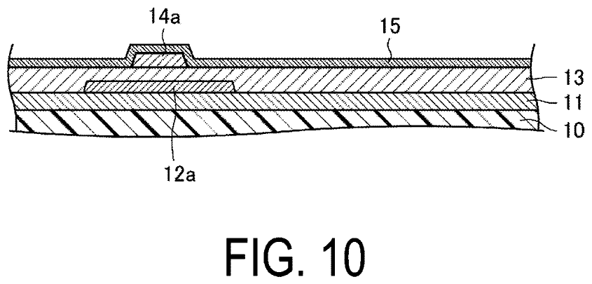

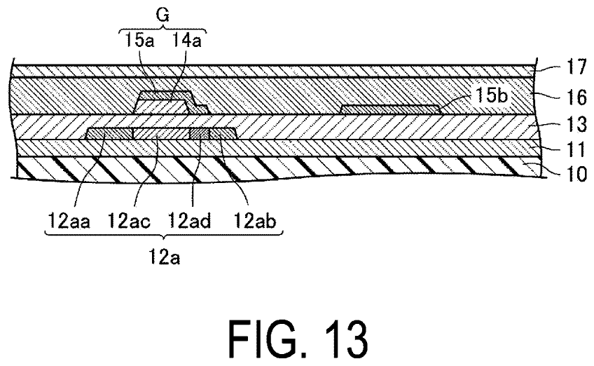

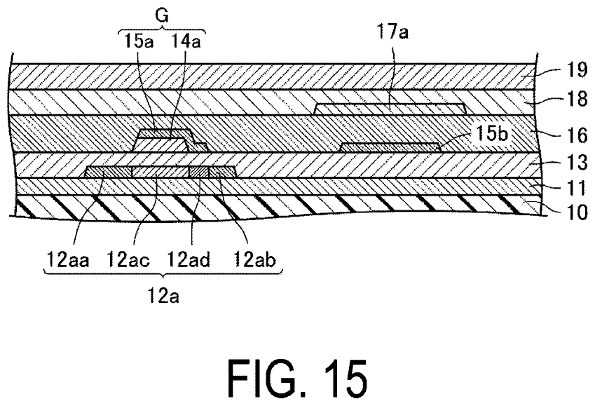

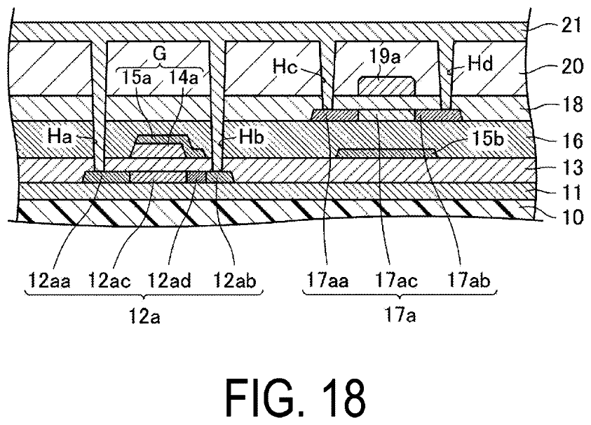

As illustrated in FIG. 3, in the TFT layer 30a, a base coat film 11, a first semiconductor film 12 described later (see FIG. 6), a first gate insulating film (first inorganic insulating film) 13, a first metal film 14 described later (see FIG. 8), a second metal film 15 described later (see FIG. 10), a first interlayer insulating film (second inorganic insulating film) 16, a second semiconductor film 17 described later (see FIG. 13), a second gate insulating film (third inorganic insulating film) 18, a third metal film 19 described later (see FIG. 15), a second interlayer insulating film (fourth inorganic insulating film) 20, a fourth metal film 21 described later (see FIG. 18), the protective insulating film 22, and the flattening film 23 are sequentially layered on the resin substrate 10. Here, the gate line 14g and the light emission control line 14e are formed of a first metal film. The second initialization power source line 19i is formed of the third metal film 19. The source line 21f and the power source line 21g are formed of the fourth metal film 21.

Each of the base coat film 11, the first gate insulating film 13, the first interlayer insulating film 16, the second gate insulating film 18, the second interlayer insulating film 20, and the protective insulating film 22 is composed of, for example, a single-layer film or a layered film of an inorganic insulating film such as silicon nitride, silicon oxide, or silicon oxynitride. Here, at least a portion of the first interlayer insulating film 16 on a second semiconductor layer 17a side described below and a portion of the second gate insulating film 18 on the second semiconductor layer 17a side are each formed of, for example, a silicon oxide film.

As illustrated in FIG. 3, the first TFT 9A includes a first semiconductor layer 12a provided on the base coat film 11, the first gate insulating film 13 provided on the first semiconductor layer 12a, a first gate electrode G provided on the first gate insulating film 13, the first interlayer insulating film 16, the second gate insulating film 18, and the second interlayer insulating film 20 sequentially provided so as to cover the first gate electrode G, and a first terminal electrode 21a and a second terminal electrode 21b provided on the second interlayer insulating film 20 so as to be separated from each other.

The first semiconductor layer 12a is formed of the first semiconductor film 12, made of, for example, polysilicon such as low temperature polysilicon (LTPS), and, as illustrated in FIG. 3, includes a first conductor region 12aa and a second conductor region 12ab defined so as to be separated from each other, a first channel region 12ac defined between the first conductor region 12aa and the second conductor region 12ab, and a lightly doped drain (LDD) region 12ad defined between the second conductor region 12ab and the first channel region 12ac. Here, the LDD region 12ad is a low-concentration impurity region having an impurity concentration lower than those of the first conductor region 12aa and the second conductor region 12ab, and, as illustrated in FIG. 3, is provided so as to overlap a portion of a thin film electrode portion 15a protruding from a thick film electrode portion 14a described later.

The first gate electrode G is formed of a layered film of the first metal film 14 having a relatively thick film thickness and the second metal film 15 having a relatively thin film thickness, as illustrated in FIG. 3, is provided so as to overlap the first channel region 12ac of the first semiconductor layer 12a, and is configured to control conduction between the first conductor region 12aa and the second conductor region 12ab of the first semiconductor layer 12a. As illustrated in FIG. 3, the first gate electrode G includes the thick film electrode portion 14a formed of the first metal film 14, and the thin film electrode portion 15a formed of the second metal film 15 so as to overlap the thick film electrode portion 14a and protrude from the thick film electrode portion 14a toward one side in a channel length direction (X direction in the drawing). Here, as illustrated in FIG. 3, the thin film electrode portion 15a is provided so as to cover one end portion of the thick film electrode portion 14a in the channel length direction (positive side in the X direction in the drawing) in a cross-sectional view.

The first terminal electrode 21a and the second terminal electrode 21b are formed of the fourth metal film 21, and, as illustrated in FIG. 3, are electrically connected to the first conductor region 12aa and the second conductor region 12ab of the first semiconductor layer 12a through a first contact hole Ha and a second contact hole Hb, respectively, formed in a layered film of the first gate insulating film 13, the first interlayer insulating film 16, the second gate insulating film 18, and the second interlayer insulating film 20.

As illustrated in FIG. 3, the second TFT 9B includes the second semiconductor layer 17a provided on the first interlayer insulating film 16, the second gate insulating film 18 provided on the second semiconductor layer 17a, the second gate electrode 19a provided on the second gate insulating film 18, the second interlayer insulating film 20 provided to cover the second gate electrode 19a, and a third terminal electrode 21c and a fourth terminal electrode 21d provided so as to be separated from each other on the second interlayer insulating film 20. A lower conductive layer 15b formed of the second metal film 15 is provided on the resin substrate 10 side of the second semiconductor layer 17a so as to overlap a second channel region 17ac described later.

The second semiconductor layer 17a is formed of the second semiconductor film 17 made of, for example, an In—Ga—Zn—O based oxide semiconductor, and includes, as illustrated in FIG. 3, a third conductor region 17aa and a fourth conductor region 17ab defined so as to be separated from each other, and the second channel region 17ac defined between the third conductor region 17aa and the fourth conductor region 17ab. Here, the In—Ga—Zn—O based semiconductor is ternary oxide of indium (In), gallium (Ga), and zinc (Zn), and a ratio (a composition ratio) of each of In, Ga, and Zn is not particularly limited to a specific value. The In—Ga—Zn—O based semiconductor may be an amorphous semiconductor or may be a crystalline semiconductor. Note that a crystalline In—Ga—Zn—O based semiconductor in which a c-axis is oriented substantially perpendicular to a layer surface is preferable as the crystalline In—Ga—Zn—O based semiconductor. In place of the In—Ga—Zn—O based semiconductor, another oxide semiconductor may be included. Examples of other oxide semiconductors may include an In—Sn—Zn—O based semiconductor (for example, In₂O₃—SnO₂—ZnO; InSnZnO). The In—Sn—Zn—O based semiconductor is ternary oxide of indium (In), tin (Sn), and zinc (Zn). Alternatively, examples of other oxide semiconductors may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that as the Zn—O based semiconductor, a semiconductor in a non-crystalline (amorphous) state of ZnO to which one kind or a plurality of kinds of impurity elements among group 1 elements, group 13 elements, group 14 elements, group 15 elements, group 17 elements, and the like are added, a polycrystalline state, or a microcrystalline state in which the non-crystalline state and the polycrystalline state are mixed, or a semiconductor to which no impurity element is added can be used.

The second gate electrode 19a is formed of the third metal film 19, is, as illustrated in FIG. 3, provided so as to overlap the second channel region 17ac of the second semiconductor layer 17a, and is configured to control conduction between the third conductor region 17aa and the fourth conductor region 17ab of the second semiconductor layer 17a.

The third terminal electrode 21c and the fourth terminal electrode 21d are formed of the fourth metal film 21, and, as illustrated in FIG. 3, are electrically connected to the third conductor region 17aa and the fourth conductor region 17ab of the second semiconductor layer 17a through a third contact hole Hc and a fourth contact hole Hd, respectively, formed in a layered film of the second gate insulating film 18 and the second interlayer insulating film 20.

As described above, the lower conductive layer 15b is configured to overlap the second channel region 17ac of the second semiconductor layer 17a to prevent light from being incident on the second channel region 17ac and prevent impurity ions included in the resin substrate 10 from reaching the second channel region 17ac. Further, the lower conductive layer 15b may be electrically connected to the second gate electrode 19a, so that the second TFT 9B has a double gate structure to improve performances of the second TFT 9B.

In the present embodiment, a write TFT 9c, a drive TFT 9d, a power supply TFT 9e, and a light-emission control TFT 9f, which will be described below, are exemplified as the four first TFTs 9A including the first semiconductor layer 12a formed of polysilicon, and an initialization TFT 9a, a compensation TFT 9b, and an anode discharge TFT 9g, which will be described below, are exemplified as the three second TFTs 9B including the second semiconductor layer 17a formed of the oxide semiconductor (see FIG. 4). In the equivalent circuit diagram in FIG. 4, the first and second terminal electrodes 21a and 21b of each of the TFTs 9c, 9d, 9e, and 9f are indicated by circled numbers 1 and 2, respectively, and the third and fourth terminal electrodes 21c and 21d of each of the TFTs 9a, 9b, and 9g are indicated by circled numbers 3 and 4, respectively. In the equivalent circuit diagram in FIG. 4, the pixel circuit of the subpixel P in the n-th row and the m-th column is illustrated, but a part of the pixel circuit of the subpixel P in the (n−1)-th row and the m-th column is also included. In the equivalent circuit diagram in FIG. 4, the power source line 21g for supplying a high power supply voltage ELVDD also serves as a first initialization power source line, but the power source line 21g and the first initialization power source line may be provided separately. The same voltage as that of a low power supply voltage ELVSS is input to the second initialization power source line 19i, but is not limited thereto; a voltage that is different from the low power supply voltage ELVSS and turns off an organic EL element 35 described below may be input.

As illustrated in FIG. 4, in each subpixel P, a gate electrode of the initialization TFT 9a is electrically connected to a gate line 14g(n−1) of the previous stage ((n−1)-th stage), a third terminal electrode of the initialization TFT 9a is electrically connected to a lower conductive layer of the capacitor 9h, which will be described later, and a gate electrode of the drive TFT 9d, and a fourth terminal electrode of the initialization TFT 9a is electrically connected to the power source line 21g.

As illustrated in FIG. 4, in each subpixel P, a gate electrode of the compensation TFT 9b is electrically connected to a gate line 14g(n) of the own stage (n-th stage), a third terminal electrode of the compensation TFT 9b is electrically connected to the gate electrode of the drive TFT 9d, and a fourth terminal electrode of the compensation TFT 9b is electrically connected to a first terminal electrode of the drive TFT 9d.

As illustrated in FIG. 4, in each subpixel P, the gate electrode of the write TFT 9c is electrically connected to the gate line 14g(n) of the own stage (n-th stage), the first terminal electrode of the write TFT 9c is electrically connected to the corresponding source line 21f, and the second terminal electrode of the write TFT 9c is electrically connected to the second terminal electrode of the drive TFT 9d.

As illustrated in FIG. 4, in each subpixel P, the gate electrode of the drive TFT 9d is electrically connected to each of the third terminal electrodes of the initialization TFT 9a and the compensation TFT 9b, the first terminal electrode of the drive TFT 9d is electrically connected to the fourth terminal electrode of the compensation TFT 9b and a second terminal electrode of the power supply TFT 9e, and the second terminal electrode of the drive TFT 9d is electrically connected to the second terminal electrode of the write TFT 9c and the first terminal electrode of the light-emission control TFT 9f. Here, the drive TFT 9d is configured to control a drive current of the organic EL element 35.

As illustrated in FIG. 4, in each subpixel P, the gate electrode of the power supply TFT 9e is electrically connected to the light emission control line 14e of the own stage (n-th stage), the first terminal electrode of the power supply TFT 9e is electrically connected to the power source line 21g, and the second terminal electrode of the power supply TFT 9e is electrically connected to the first terminal electrode of the drive TFT 9d.

As illustrated in FIG. 4, in each subpixel P, a gate electrode of the light-emission control TFT 9f is electrically connected to the light emission control line 14e of the own stage (n-th stage), the first terminal electrode of the light-emission control TFT 9f is electrically connected to the second terminal electrode of the drive TFT 9d, and the second terminal electrode of the light-emission control TFT 9f is electrically connected to a first electrode 31 of the organic EL element 35, which will be described later.

As illustrated in FIG. 4, in each subpixel P, the gate electrode of the anode discharge TFT 9g is electrically connected to the gate line 14g(n) of the own stage (n-th stage), the third terminal electrode of the anode discharge TFT 9g is electrically connected to the first electrode 31 of the organic EL element 35, and the fourth terminal electrode of the anode discharge TFT 9g is electrically connected to the second initialization power source line 19i.

The capacitor 9h includes, for example, a lower conductive layer (not illustrated) formed of the first metal film 14, the first interlayer insulating film 16 and the second gate insulating film 18 provided to cover the lower conductive layer, and an upper conductive layer (not illustrated) provided on the second gate insulating film 18 so as to overlap the lower conductive layer and formed of the third metal film 19. As illustrated in FIG. 4, in each subpixel P, the lower conductive layer of the capacitor 9h is electrically connected to the gate electrode of the drive TFT 9d and each of the third terminal electrodes of the initialization TFT 9a and the compensation TFT 9b, the upper conductive layer of the capacitor 9h is electrically connected to the third terminal electrode of the anode discharge TFT 9g, the second terminal electrode of the light-emission control TFT 9f, and the first electrode 31 of the organic EL element 35.

The flattening film 23 has a flat surface in the display region D, and is made of, for example, an organic resin material such as a polyimide resin or an acrylic resin, or a polysiloxane-based spin on glass (SOG) material.

As illustrated in FIG. 3, the organic EL element layer 40 includes a plurality of the organic EL elements 35 provided as a plurality of the light-emitting elements to be arrayed in a matrix shape corresponding to the plurality of subpixels P, and edge covers 32 provided in a lattice pattern common to all the subpixels P in such a manner as to cover a peripheral end portion of the first electrode 31 of each organic EL element 35.

As illustrated in FIG. 3, the organic EL element 35 includes, in each subpixel P, the first electrode 31 provided on the flattening film 23 of the TFT layer 30a, the organic EL layer 33 provided on the first electrode 31, and a second electrode 34 provided on the organic EL layer 33.

The first electrode 31 is electrically connected to the second terminal electrode of the light-emission control TFT 9f of each of the subpixels P, through a contact hole formed in a layered film of the protective insulating film 22 and the flattening film 23. Further, the first electrode 31 functions to inject holes (positive holes) into the organic EL layer 33. Further, the first electrode 31 is preferably made of a material having a large work function to improve the efficiency of hole injection into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the materials constituting the first electrode 31 may include an alloy such as astatine (At)/astatine oxide (AtO₂). Furthermore, examples of the materials constituting the first electrode 31 may include an electrically conductive oxide such as tin oxide (SnO), zinc oxide (ZnO), indium tin oxide (ITO), and indium zinc oxide (IZO). Additionally, the first electrode 31 may be formed by layering a plurality of layers made of any of the materials described above. Note that examples of compound materials having a high work function include indium tin oxide (ITO) and indium zinc oxide (IZO).

As illustrated in FIG. 5, the organic EL layer 33 includes a hole injection layer 1, a hole transport layer 2, a light-emitting layer 3, an electron transport layer 4, and an electron injection layer 5, which are sequentially provided on the first electrode 31.

The hole injection layer 1 is also referred to as an anode buffer layer, and functions to reduce an energy level difference between the first electrode 31 and the organic EL layer 33 to thereby improve the efficiency of hole injection into the organic EL layer 33 from the first electrode 31. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 31 to the organic EL layer 33. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 31 and the second electrode 34, respectively, and the holes and the electrons recombine, in a case where a voltage is applied via the first electrode 31 and the second electrode 34. Here, the light-emitting layer 3 is made of a material having high luminous efficiency. Moreover, examples of materials constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of causing electrons to efficiently migrate to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 functions to reduce an energy level difference between the second electrode 34 and the organic EL layer 33 to thereby improve the efficiency of electron injection into the organic EL layer 33 from the second electrode 34, and this function allows the drive voltage of the organic EL element 35 to be reduced. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 34 is provided in common to all the subpixels P to cover each of the organic EL layer 33 and the edge cover 32. Further, the second electrode 34 functions to inject electrons into the organic EL layer 33. Further, the second electrode 34 is preferably made of a material having a low work function to improve the efficiency of electron injection into the organic EL layer 33. Here, examples of a material constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be formed of alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al). Further, the second electrode 34 may be formed of an electrically conductive oxide such as tin oxide (SnO), zinc oxide (ZnO), indium tin oxide (ITO), and indium zinc oxide (IZO). Further, the second electrode 34 may be formed by layering a plurality of layers made of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as a polyimide resin or an acrylic resin, or an SOG material of a polysiloxane based. As illustrated in FIG. 3, the sealing film 45 is provided to cover the second electrode 34, and includes a first inorganic sealing film 41, an organic sealing film 42, and a second inorganic sealing film 43 sequentially layered on the second electrode 34, and has a function to protect the organic EL layer 33 of the organic EL element layer 35 from moisture and oxygen.

The first inorganic sealing film 41 and the second inorganic sealing film 43 are constituted of, for example, an inorganic insulating film such as a silicon nitride film, a silicon oxide film, or a silicon oxynitride film.

The organic sealing film 42 is made of, for example, an organic resin material such as an acrylic resin, an epoxy resin, a silicone resin, a polyurea resin, a parylene resin, a polyimide resin, a polyamide resin, or the like.

In the organic EL display device 50a having the configuration described above, in each subpixel P, when the light emission control line 14e is first selected and deactivated, the organic EL element 35 is brought into a non-light emission state. In the non-light emission state, the gate line 14g(n−1) of the previous stage is selected, and a gate signal is input to the initialization TFT 9a via the gate line 14g(n−1), so that the initialization TFT 9a is brought into an on state, thereby applying a high power supply voltage ELVDD of the power source line 21g to the capacitor 9h and bringing the drive TFT 9d into an on state. Thereby, the charge of the capacitor 9h is discharged to initialize the voltage applied to the gate electrode of the drive TFT 9d. Subsequently, the gate line 14g(n) of the own stage is selected and activated, so that the compensation TFT 9b and the write TFT 9c are brought into the on state. Then, a predetermined voltage corresponding to a source signal transmitted via the corresponding source line 21f is written to the capacitor 9h via the drive TFT 9d in the diode-connected state and the anode discharge TFT 9g is brought into the on state, and an initialization signal is applied to the first electrode 31 of the organic EL element 35 via the second initialization power source line 19i to reset the charge accumulated in the first electrode 31. Thereafter, the light emission control line 14e is selected, and the power supply TFT 9e and the light-emission control TFT 9f are brought into an on state, so that a drive current corresponding to the voltage applied to the gate electrode of the drive TFT 9d is supplied to the organic EL element 35 from the power source line 21g. Thus, in the organic EL display device 50a, the organic EL element 35 in each subpixel P emits light with luminance corresponding to the drive current, and an image is displayed.

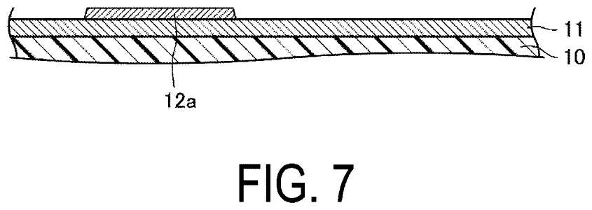

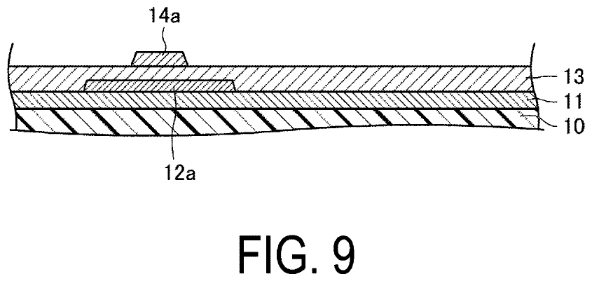

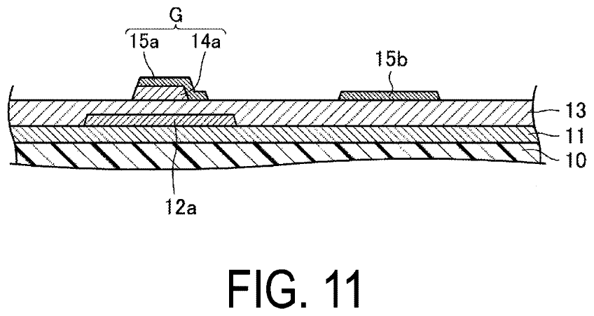

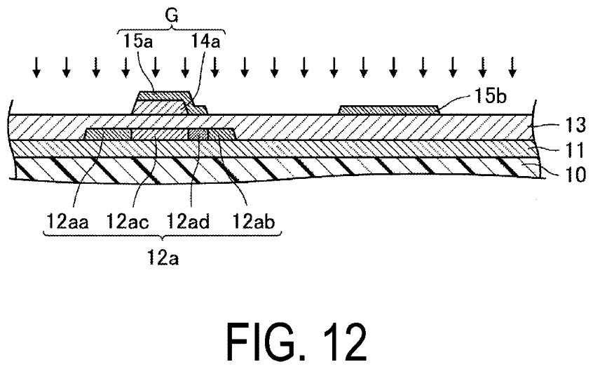

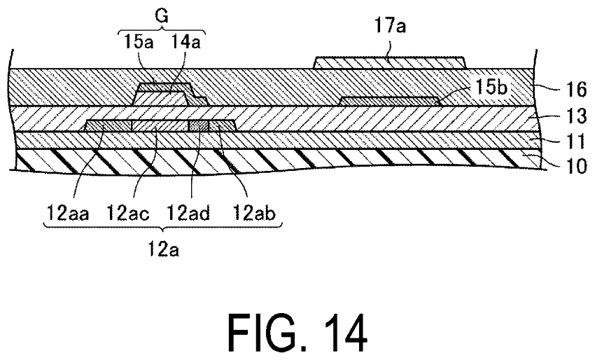

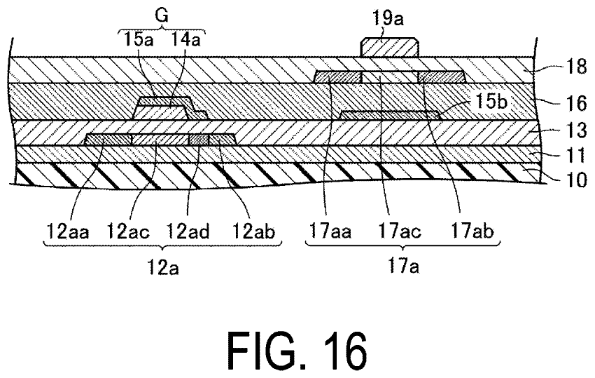

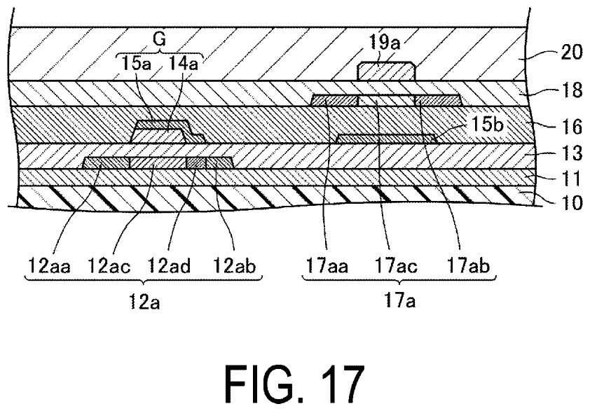

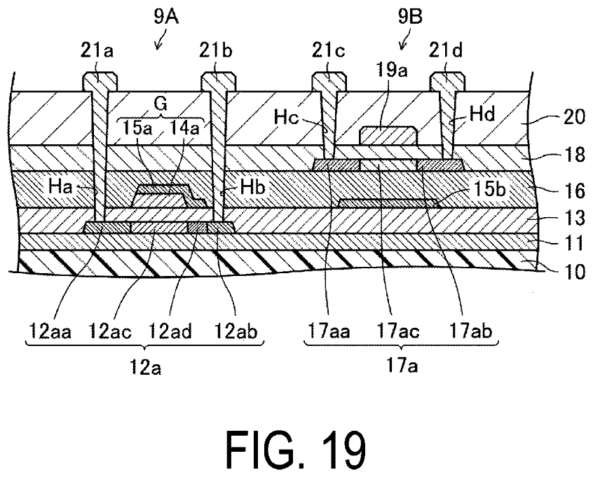

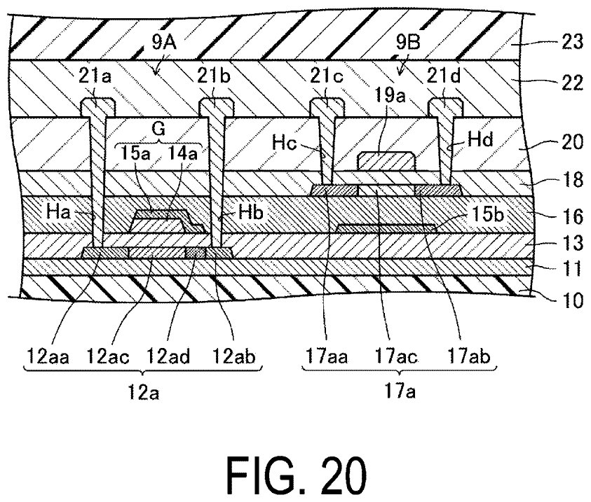

Next, a method for manufacturing the organic EL display device 50a according to the present embodiment will be described. Note that the method for manufacturing the organic EL display device 50a includes a TFT layer forming step, an organic EL element layer forming step, and a sealing film forming step. FIG. 6, FIG. 7, FIG. 8, FIG. 9, FIG. 10, FIG. 11, FIG. 12, FIG. 13, FIG. 14, FIG. 15, FIG. 16, FIG. 17, FIG. 18, FIG. 19, and, FIG. 20 are a first, a second, a third, a fourth, a fifth, a sixth, a seventh, an eighth, a ninth, a tenth, an eleventh, a twelfth, a thirteenth, a fourteenth, and a fifteenth cross-sectional views, respectively, each for sequentially depicting a part of the manufacturing process (TFT layer forming step) of the organic EL display device.

### TFT Layer Forming Step

First, for example, a silicon nitride film (about 50 nm) and a silicon oxide film (having a thickness of about 250 nm) are sequentially formed on the resin substrate 10 formed on a glass substrate by, for example, plasma chemical vapor deposition (CVD), to form the base coat film 11.

Subsequently, an amorphous silicon film (having a thickness of about 50 nm) is formed on a substrate surface on which the base coat film 11 is formed by, for example, plasma CVD, and the amorphous silicon film is crystallized by laser annealing or the like to form the first semiconductor film 12 made of polysilicon as illustrated in FIG. 6. Thereafter, the first semiconductor film 12 is patterned to form the first semiconductor layer 12a as illustrated in FIG. 7.

Further, a silicon oxide film (having a thickness of about 100 nm) is formed on the substrate surface on which the first semiconductor layer 12a is formed by, for example, plasma CVD to form the first gate insulating film 13. Thereafter, a molybdenum film (having a thickness of about 150 nm) is formed by, for example, sputtering to form the first metal film 14 as illustrated in FIG. 8.

Thereafter, the first metal film 14 is patterned to form the thick film electrode portion 14a and the like as illustrated in FIG. 9.

Next, a molybdenum film (having a thickness of about 30 nm) is formed by, for example, sputtering on the substrate surface on which the thick film electrode portion 14a is formed to form the second metal film 15 as illustrated in FIG. 10.

Thereafter, the second metal film 15 is patterned to form the thin film electrode portion 15a, the first gate electrode G, and the lower conductive layer 15b as illustrated in FIG. 11.

Further, as illustrated in FIG. 12, by doping the first semiconductor layers 12a with impurity ions such as phosphorus in each of the first semiconductor layers 12ab by using the first gate electrode G formed of the thick film electrode portion 14a and the thin film electrode portion 15a as a mask, the first conductor region 12aa, the second conductor region 12ab, the first channel region 12ac, and the LDD region 12ad are formed in the first semiconductor layers 12a. Here, the portion of the thin film electrode portion 15a protruding from the thick film electrode portion 14a serving as the mask is thinner than a portion where the thick film electrode portion 14a and the thin film electrode portion 15a similarly serving as the mask are layered, so that a small amount of impurity ions pass through the portion to form the LDD region 12ad in a self-aligned manner in the first semiconductor layer 12a.

Subsequently, a silicon nitride film (about 150 nm) and a silicon oxide film (having a thickness of about 100 nm) are sequentially formed by, for example, plasma CVD on the substrate surface doped with impurity ions to form the first interlayer insulating film 16, and then an oxide semiconductor film (having a thickness of about 30 nm) of InGaZnO₄ or the like is formed by, for example, sputtering to form the second semiconductor film 17 as illustrated in FIG. 13.

Thereafter, the second semiconductor film 17 is patterned to form the second semiconductor layer 17a as illustrated in FIG. 14.

Further, a silicon oxide film (having a thickness of about 100 nm) is formed on the substrate surface on which the second semiconductor layer 17a is formed by, for example, plasma CVD to form the second gate insulating film 18. Thereafter, a molybdenum film (having a thickness of about 200 nm) is formed by, for example, sputtering to form the third metal film 19 as illustrated in FIG. 15.

Thereafter, the third metal film 19 is patterned to form the second gate electrode 19a and the like as illustrated in FIG. 16.

Further, a silicon oxide film (having a thickness of about 300 nm) and a silicon nitride film (having a thickness of about 150 nm) are sequentially formed by, for example, the plasma CVD method, on the substrate surface on which the second gate electrode 19a or the like is formed, thereby forming the second interlayer insulating film 20 as illustrated in FIG. 17. A part of the second semiconductor layer 17a is made conductive by heat treatment after the formation of the second interlayer insulating film 20, so that the third conductor region 17aa, the fourth conductor region 17ab, and the second channel region 17ac are formed in the second semiconductor layer 17a.

Subsequently, the first gate insulating film 13, the first interlayer insulating film 16, the second gate insulating film 18, and the second interlayer insulating film 20 are patterned to the substrate surface on which the second interlayer insulating film 20 is formed to form the first contact hole Ha, the second contact hole Hb, the third contact hole Hc, the fourth contact hole Hd, and the like, and then a titanium film (having a thickness of about 50 nm), an aluminum film (having a thickness of about 400 nm), a titanium film (having a thickness of about 50 nm), and the like are sequentially formed by, for example, sputtering to form the fourth metal film 21 as illustrated in FIG. 18.

Thereafter, the fourth metal film 21 is patterned to form the first, second, third and fourth terminal electrodes 21a, 21b, 21c and 21d as illustrated in FIG. 19.

Further, after a silicon oxide film (having a thickness of about 250 nm) is formed by, for example, the plasma CVD method on the substrate surface on which the first terminal electrode 21a and the like is formed to form the protective insulating film 22, an acrylic photosensitive resin film (having a thickness of about 2 μm) is applied by, for example, spin coating or slit coating, and then pre-baking, exposing, developing, and post-baking are performed on the applied film to form the flattening film 23 including the contact hole as illustrated in FIG. 20.

Finally, the protective insulating film 21 exposed from the contact hole of the flattening film 23 is removed so that the contact hole reaches the second terminal electrode of the light-emission control TFT 9f.

As described above, the TFT layer 30a can be formed.

### Organic EL Element Layer Forming Step

The organic EL element layer 40 is formed by forming the first electrode 31, the edge cover 32, the organic EL layer 33 (the hole injection layer 1, the hole transport layer 2, the light-emitting layer 3, the electron transport layer 4, the electron injection layer 5), and the second electrode 34 on the flattening film 23 of the TFT layer 30a having been formed in the TFT layer forming step, by using a known method.

### Sealing Film Forming Step

First, an inorganic insulating film such as a silicon nitride film, a silicon oxide film, or a silicon oxynitride film is formed by plasma CVD on a substrate surface formed with the organic EL element layer 40 formed in the organic EL element layer forming step described above by using a mask to form the first inorganic sealing film 41.

Next, on the substrate surface formed of the first inorganic sealing film 41, a film made of an organic resin material such as acrylic resin is formed by, for example, using an ink-jet method to form the organic sealing film 42.

Thereafter, an inorganic insulating film such as a silicon nitride film, a silicon oxide film, or a silicon oxynitride film is formed by plasma CVD on the substrate surface formed with the organic sealing film 42 by using a mask to form the second inorganic sealing film 43, thereby forming the sealing film 45.

Finally, after a protective sheet (not illustrated) is applied to the substrate surface formed with the sealing film 45, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off.

The organic EL display device 50a of the present embodiment can be manufactured as described above.

As described above, according to the organic EL display device 50a of the present embodiment, in the first TFT 9A, the LDD region 12ad having an impurity concentration lower than that of the second conductor region 12ab is provided between the first channel region 12ac and the second conductor region 12ab in the first semiconductor layer 12a, so that electric field concentration in the second conductor region 12ab can be relaxed, and the characteristics of the first TFT 9A can be stabilized. Here, the first gate electrode G of the first TFT 9A includes the thick film electrode portion 14a formed of the first metal film 14 having a relatively large thickness and the thin film electrode portion 15a formed of the second metal film 15 having a relatively small thickness so as to overlap the thick film electrode portion 14a and protrude from the thick film electrode portion 14a toward one side in the channel length direction. The LDD region 12ad is provided so as to overlap the portion of the thin film electrode portion 15a protruding from the thick film electrode portion 14a of the first gate electrode G. Thus, the LDD region 12ad is formed in a self-aligned manner so as to overlap the portion of the thin film electrode portion 15a protruding from the thick film electrode portion 14a by doping the first semiconductor layer 12a with impurity ions using the first gate electrode G as a mask. Further, in the second TFT 9B, the lower conductive layer 15b formed of the second metal film 15 having a relatively small thickness is provided on the resin substrate 10 side of the second semiconductor layer 17a so as to overlap the second channel region 17ac, so that the incidence of light on the second channel region 17ac can be suppressed while suppressing the deterioration of the characteristics of the second TFT 9B due to a covering property of the first interlayer insulating film 16. When the lower conductive layer 15b is formed of the first metal film 14 having a relatively large thickness, the covering property of the first interlayer insulating film 16 covering the lower conductive layer 15b is deteriorated, so that the characteristics of the second TFT 9B may be deteriorated. As described above, the first gate electrode G has a two layer layered structure of the thick film electrode portion 14a and the thin film electrode portion 15a, so that the LDD region 12ad for stabilizing the characteristics of the first TFT 9A is formed in the first semiconductor layer 12a of the first TFT 9A, and the lower conductive layer 15b for suppressing the incidence of light on the second channel region 17ac is formed on the resin substrate 10 side of the second TFT 9B. Thus, in the organic EL display device 50a having the hybrid structure, the characteristics of the first TFT 9A using the polysilicon semiconductor can be stabilized and the deterioration of the characteristics of the second TFT 9B using the oxide semiconductor due to the light incidence can be suppressed, as efficiently as possible.

According to the organic EL display device 50a of the present embodiment, the first TFT 9A is provided to constitute the drive TFT 9d. Here, in the first TFT 9A, as described above, the electric field concentration in the second conductor region 12ab can be relaxed by the arrangement of the LDD region 12ad, so that, in the output characteristics of the drive TFT 9d, high saturation performance with stable current change with respect to an applied voltage can be obtained, and the occurrence of luminance unevenness, image sticking, and the like can be suppressed.

According to the organic EL display device 50a of the present embodiment, the LDD region 12ad is provided between the first channel region 12ac and the second conductor region 12ab in the first semiconductor layer 12a of the first TFT 9A, so that an off current of the first TFT 9A can be reduced.

According to the organic EL display device 50a of the present embodiment, in the second TFT 9B, the lower conductive layer 15b is provided on the resin substrate 10 side of the second semiconductor layer 17a so as to overlap the second channel region 17ac, so that diffusion of impurity ions included in the resin substrate 10 into the second channel region 17ac can be suppressed, and deterioration of the characteristics of the second TFT 9B can be suppressed.

### Second Embodiment

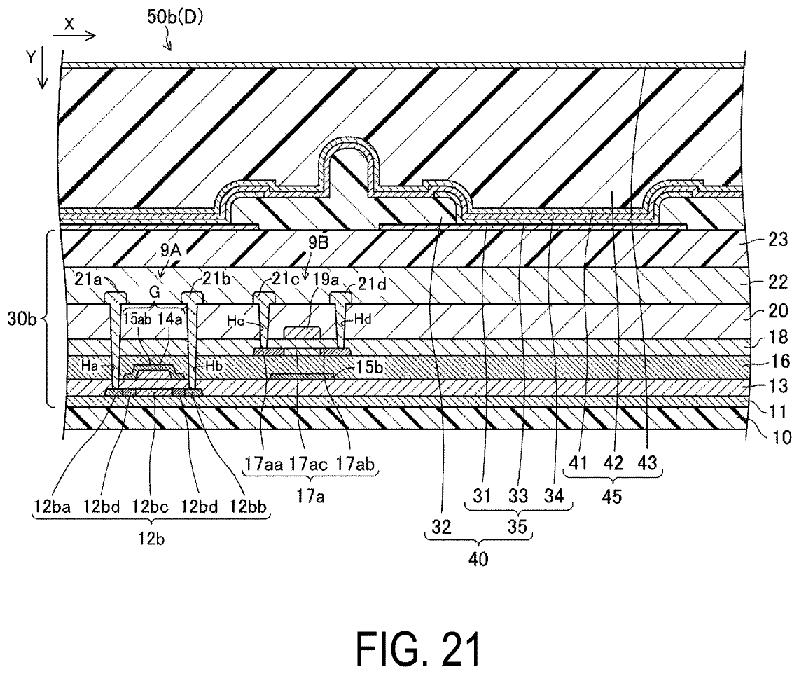

FIG. 21 illustrates a second embodiment of a display device according to the disclosure. Here, FIG. 21 is a cross-sectional view of a display region D of an organic EL display device 50b according to the present embodiment, and is a view corresponding to FIG. 3 described in the above-described first embodiment. Note that, in each of the following embodiments, the same portions as those in FIG. 1 to FIG. 20 are denoted by the same reference signs, and the detailed description of these portions are omitted.

In the first embodiment described above, the organic EL display device 50a is exemplified in which the first semiconductor layer 12a including one LDD region 12ad is provided. However, in the present embodiment, the organic EL display device 50b provided with a first semiconductor layer 12b including two LDD regions 12bd is exemplified.

As with the organic EL display device 50a of the first embodiment described above, the organic EL display device 50b includes, for example, the display region D provided in a rectangular shape and a frame region F provided in a periphery of the display region D.

As illustrated in FIG. 21, the organic EL display device 50b includes the resin substrate 10, the TFT layer 30b provided on the resin substrate 10, the organic EL element layer 40 provided on the TFT layer 30b, and the sealing film 45 provided on the organic EL element layer 40.

As illustrated in FIG. 21, as with the TFT layer 30a of the first embodiment described above, the TFT layer 30c includes the base coat film 11 provided on the resin substrate 10, four first TFTs 9A, three second TFTs 9B, and one capacitor 9h (see FIG. 4) provided on the base coat film 11 for each subpixel P, and the protective insulating film 22 and the flattening film 23 sequentially provided on all of the first TFT 9A, the second TFT 9B, and the capacitor 9h. Here, as with the TFT layer 30a of the first embodiment described above, the TFT layer 30b is provided with the plurality of gate lines 14g, the plurality of light emission control lines 14e, the plurality of second initialization power source lines 19i, the plurality of source lines 21f, and the plurality of power source lines 21g.

In the TFT layer 30b, as with the TFT layer 30a of the first embodiment described above, the base coat film 11, the first semiconductor film 12, the first gate insulating film 13, the first metal film 14, the second metal film 15, the first interlayer insulating film 16, the second semiconductor film 17, the second gate insulating film 18, the third metal film 19, the second interlayer insulating film 20, the fourth metal film 21, the protective insulating film 22, and the flattening film 23 are sequentially layered on the resin substrate 10.

As illustrated in FIG. 21, the first TFT 9A includes the first semiconductor layer 12b provided on the base coat film 11, the first gate insulating film 13 provided on the first semiconductor layer 12b, the first gate electrode G provided on the first gate insulating film 13, the first interlayer insulating film 16, the second gate insulating film 18, and the second interlayer insulating film 20 sequentially provided so as to cover the first gate electrode G, and the first terminal electrode 21a and the second terminal electrode 21b provided on the second interlayer insulating film 20 so as to be separated from each other.

The first semiconductor layer 12b is formed of the first semiconductor film 12 made of, for example, polysilicon such as LTPS, and, as illustrated in FIG. 21, includes the first conductor region 12ba and the second conductor region 12bb defined so as to be separated from each other, the first channel region 12bc defined between the first conductor region 12ba and the second conductor region 12bb, and a pair of the LDD regions 12bd respectively provided between the first conductor region 12ba and the first channel region 12bc and between the second conductor region 12bb and the first channel region 12bc. Here, the LDD region 12bd is a low-concentration impurity region having an impurity concentration lower than those of the first conductor region 12ba and the second conductor region 12bb, and, as illustrated in FIG. 21, is provided so as to overlap a portion of a thin film electrode portion 15ab protruding from the thick film electrode portion 14a. In the first semiconductor layer 12b, the structure in which the LDD regions 12bd are respectively provided on the first conductor region 12ba side and the second conductor region 12bb side of the first channel region 12bc is effective for a TFT of each subpixel through which bi-directional currents flow, such as a TFT for driving a subpixel of a liquid crystal display device.

The first gate electrode G is formed of a layered film of the first metal film 14 having a relatively thick film thickness and the second metal film 15 having a relatively thin film thickness, as illustrated in FIG. 21, is provided so as to overlap the first channel region 12bc of the first semiconductor layer 12b, and is configured to control conduction between the first conductor region 12ba and the second conductor region 12bb of the first semiconductor layer 12b. As illustrated in FIG. 21, the first gate electrode G includes the thick film electrode portion 14a formed of the first metal film 14, and the thin film electrode portion 15ab formed of the second metal film 15 so as to overlap the thick film electrode portion 14a and protrude from the thick film electrode portion 14a toward one side and the other side in a channel length direction (X direction in the drawing). Here, as illustrated in FIG. 21, the thin film electrode portion 15ab is provided so as to cover both end portions of the thick film electrode portion 14a in the channel length direction (the X direction in the drawing) in a cross-sectional view.

In the organic EL display device 50b having the configuration described above, as with the organic EL display device 50a of the first embodiment described above, in each subpixel P, the organic EL element 35 emits light at luminance corresponding to a drive current to perform the image display.

The organic EL display device 50b of the present embodiment can be manufactured by changing the pattern shape when patterning the second metal film 15 in the TFT layer forming step of the method for manufacturing the organic EL display device 50a of the first embodiment.

As described above, according to the organic EL display device 50b of the present embodiment, in the first TFT 9A, the LDD regions 12bd having an impurity concentration lower than those of the first conductor region 12ba and the second conductor region 12bb are respectively provided between the first channel region 12bc and the first conductor region 12ba, and between the first channel region 12bc and the second conductor region 12bb in the first semiconductor layer 12b, so that the electric field concentration in the first conductor region 12ba and the second conductor region 12bb can be relaxed, and the characteristics of the first TFT 9A can be stabilized. Here, the first gate electrode G of the first TFT 9A includes the thick film electrode portion 14a formed of the first metal film 14 having a relatively large thickness and the thin film electrode portion 15ab formed of the second metal film 15 having a relatively small thickness so as to overlap the thick film electrode portion 14a and protrude from the thick film electrode portion 14a toward both sides in the channel length direction. The LDD region 12bd is provided so as to overlap the portion of the thin film electrode portion 15ab protruding from the thick film electrode portion 14a of the first gate electrode G. Thus, the LDD region 12bd is formed in a self-aligned manner so as to overlap the portion of the thin film electrode portion 15ab protruding from the thick film electrode portion 14a by doping the first semiconductor layer 12b with impurity ions using the first gate electrode G as a mask. Further, in the second TFT 9B, the lower conductive layer 15b formed of the second metal film 15 having a relatively small thickness is provided on the resin substrate 10 side of the second semiconductor layer 17a so as to overlap the second channel region 17ac, so that the incidence of light on the second channel region 17ac can be suppressed while suppressing the deterioration of the characteristics of the second TFT 9B due to a covering property of the first interlayer insulating film 16. When the lower conductive layer 15b is formed of the first metal film 14 having a relatively large thickness, the covering property of the first interlayer insulating film 16 covering the lower conductive layer 15b is deteriorated, so that the characteristics of the second TFT 9B may be deteriorated. As described above, the first gate electrode G has the two layer layered structure of the thick film electrode portion 14a and the thin film electrode portion 15ab, so that the LDD region 12bd for stabilizing the characteristics of the first TFT 9A is formed in the first semiconductor layer 12b of the first TFT 9A, and the lower conductive layer 15b for suppressing the incidence of light on the second channel region 17ac is formed on the resin substrate 10 side of the second TFT 9B. Thus, in the organic EL display device 50b having the hybrid structure, the characteristics of the first TFT 9A using the polysilicon semiconductor can be stabilized and the deterioration of the characteristics of the second TFT 9B using the oxide semiconductor due to the light incidence can be suppressed, as efficiently as possible.

According to the organic EL display device 50b of the present embodiment, the first TFT 9A is provided to constitute the drive TFT 9d. Here, in the first TFT 9A, as described above, the electric field concentration in the second conductor region 12bb can be relaxed by the arrangement of the LDD region 12bd, so that, in the output characteristics of the drive TFT 9d, high saturation performance with stable current change with respect to an applied voltage can be obtained, and the occurrence of luminance unevenness, image sticking, and the like can be suppressed.

According to the organic EL display device 50b of the present embodiment, the LDD region 12bd is provided between the first channel region 12bc and the second conductor region 12bb in the first semiconductor layer 12b of the first TFT 9A, so that an off current of the first TFT 9A can be reduced.

According to the organic EL display device 50b of the present embodiment, in the second TFT 9B, the lower conductive layer 15b is provided on the resin substrate 10 side of the second semiconductor layer 17a so as to overlap the second channel region 17ac, so that diffusion of impurity ions included in the resin substrate 10 into the second channel region 17ac can be suppressed, and deterioration of the characteristics of the second TFT 9B can be suppressed.

### Third Embodiment

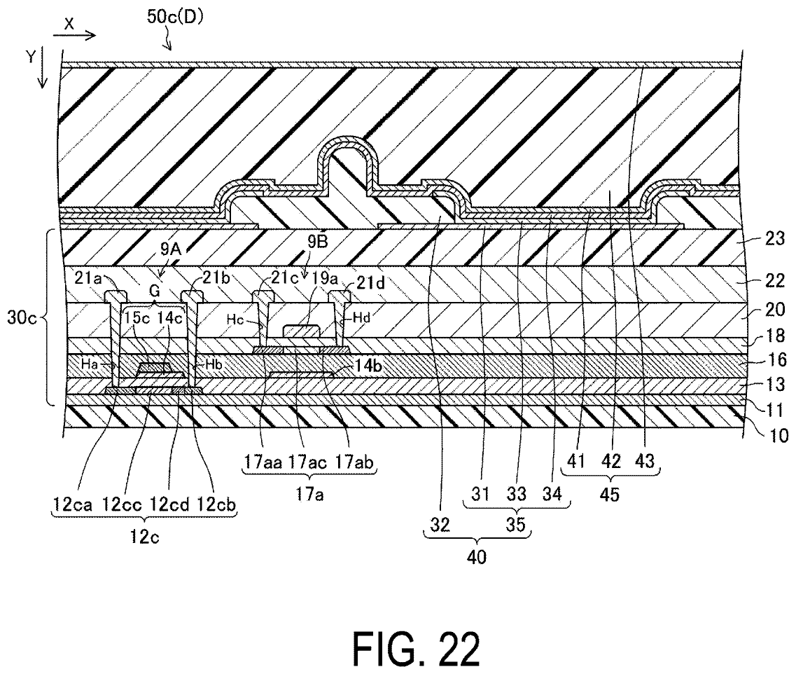

FIG. 22 illustrates a third embodiment of the display device according to the disclosure. Here, FIG. 22 is a cross-sectional view of a display region D of an organic EL display device 50c according to the present embodiment, and is a view corresponding to FIG. 3 described in the above-described first embodiment.

In the first and second embodiments, the organic EL display devices 50a and 50b are exemplified in which the first metal film 14 is formed relatively thick and the second metal film 15 is formed relatively thin. However, in the present embodiment, the organic EL display device 50c is exemplified in which the first metal film is formed relatively thin and the second metal film is formed relatively thick.

As with the organic EL display device 50a of the first embodiment described above, the organic EL display device 50c includes, for example, the display region D provided in a rectangular shape and a frame region F provided in a periphery of the display region D.

As illustrated in FIG. 22, the organic EL display device 50c includes the resin substrate 10, the TFT layer 30c provided on the resin substrate 10, the organic EL element layer 40 provided on the TFT layer 30c, and the sealing film 45 provided on the organic EL element layer 40.

As illustrated in FIG. 22, as with the TFT layer 30a of the first embodiment described above, the TFT layer 30a includes the base coat film 11 provided on the resin substrate 10, four first TFTs 9A, three second TFTs 9B, and one capacitor 9h (see FIG. 4) provided on the base coat film 11 for each subpixel P, and the protective insulating film 22 and the flattening film 23 sequentially provided on all of the first TFT 9A, the second TFT 9B, and the capacitor 9h. Here, as with the TFT layer 30a of the first embodiment described above, the TFT layer 30c is provided with the plurality of gate lines, the plurality of light emission control lines, the plurality of second initialization power source lines 19i, the plurality of source lines 21f, and the plurality of power source lines 21g. In the TFT layer 30c, the plurality of gate lines and the plurality of light emission control lines are formed not of the first metal film having a relatively small thickness but of the second metal film having a relatively large thickness.

In the TFT layer 30c, as with the TFT layer 30a of the first embodiment described above, the base coat film 11, the first semiconductor film 12, the first gate insulating film 13, the first metal film, the second metal film, the first interlayer insulating film 16, the second semiconductor film 17, the second gate insulating film 18, the third metal film 19, the second interlayer insulating film 20, the fourth metal film 21, the protective insulating film 22, and the flattening film 23 are sequentially layered on the resin substrate 10.

As illustrated in FIG. 22, the first TFT 9A includes the first semiconductor layer 12c provided on the base coat film 11, the first gate insulating film 13 provided on the first semiconductor layer 12c, the first gate electrode G provided on the first gate insulating film 13, the first interlayer insulating film 16, the second gate insulating film 18, and the second interlayer insulating film 20 sequentially provided so as to cover the first gate electrode G, and the first terminal electrode 21a and the second terminal electrode 21b provided on the second interlayer insulating film 20 so as to be separated from each other.

The first semiconductor layer 12c is formed of the first semiconductor film 12, made of, for example, polysilicon such as LTPS, and, as illustrated in FIG. 21, includes a first conductor region 12ca and a second conductor region 12cb defined so as to be separated from each other, a first channel region 12cc defined between the first conductor region 12ca and the second conductor region 12cb, and a LDD region 12cd defined between the second conductor region 12cb and the first channel region 12cc. Here, the LDD region 12cd is a low-concentration impurity region having an impurity concentration lower than that of the second conductor region 12cb, and, as illustrated in FIG. 22, is provided so as to overlap a portion of a thin film electrode portion 14c protruding from a thick film electrode portion 15c described later.

The first gate electrode G is formed of a layered film of a first metal film having a relatively thin film thickness and a second metal film having a relatively thick film thickness, as illustrated in FIG. 22, is provided so as to overlap the first channel region 12cc of the first semiconductor layer 12c, and is configured to control conduction between the first conductor region 12ca and the second conductor region 12cb of the first semiconductor layer 12c. As illustrated in FIG. 22, the first gate electrode G includes the thick film electrode portion 15c formed of the second metal film, and the thin film electrode portion 14c formed of the first metal film so as to overlap the thick film electrode portion 15c and protrude from the thick film electrode portion 15c toward one side in the channel length direction (X direction in the drawing). Here, as illustrated in FIG. 22, the thin film electrode portion 14c is provided so as to cover one end portion of the thick film electrode portion 15c in the channel length direction (positive side in the X direction in the drawing) in a cross-sectional view.

A lower conductive layer 14b formed of the first metal film is provided on the resin substrate 10 side of the second semiconductor layer 17a in the second TFT 9B so as to overlap the second channel region 17ac.

In the organic EL display device 50c having the configuration described above, as with the organic EL display device 50a of the first embodiment described above, in each subpixel P, the organic EL element 35 emits light at luminance corresponding to a drive current to perform the image display.

The organic EL display device 50c of the present embodiment can be manufactured by, for example, forming a molybdenum film (having a thickness of about 30 nm) or the like to form the first metal film, changing the pattern shape when patterning the first metal film, forming a tungsten film (having a thickness of about 150 nm) or the like to form the second metal film, and changing the pattern shape when patterning the second metal film in the TFT layer forming step of the method for manufacturing the organic EL display device 50a of the first embodiment described above. Examples of a metal constituting the first metal film and the second metal film preferably include metals having a high melting point, such as molybdenum, tungsten, tantalum, or chromium, and the first metal film and the second metal film may be made of the same material or different materials. As a metal constituting the first metal film and the second metal film, a high melting point metal such as tungsten, chromium, tantalum, tantalum nitride or molybdenum, or an alloy or a compound including the high melting point metal as a main component may be used. The manufacturing cost can be reduced by utilizing a difference in etching rate between the first metal film and the second metal film. As a specific forming method, in order to generate the difference in the etching rate when patterning the first metal film and the second metal film by dry etching, for example, a tantalum nitride film as the first metal film and a tungsten film as the second metal film are sequentially formed by, for example, sputtering, a resist is applied onto the second metal film by an application method, and the resist is exposed using a gray-tone mask, so that a thick film portion and a thin film portion are disposed in a region where the first gate electrode G is to be formed and a resist pattern in which the thin film portion is disposed is formed in a region where the lower conductive layer 14b is to be formed. Thereafter, patterning is performed by dry etching using an etching gas such as CF₄, SF₆, Cl₂, or O₂, so that the thick film electrode portion 15c and the thin film electrode portion 14c of the first gate electrode G and the lower conductive layer 14b can be formed at the same time and the manufacturing cost can be reduced.

As described above, according to the organic EL display device 50c of the present embodiment, in the first TFT 9A, the LDD region 12cd having an impurity concentration lower than that of the second conductor region 12cb is provided between the first channel region 12cc and the second conductor region 12cb in the first semiconductor layer 12c, so that electric field concentration in the second conductor region 12cb can be relaxed, and the characteristics of the first TFT 9A can be stabilized. Here, the first gate electrode G of the first TFT 9A includes the thick film electrode portion 15c formed of the second metal film having a relatively large thickness and the thin film electrode portion 14c formed of the first metal film having a relatively small thickness so as to overlap the thick film electrode portion 15c and protrude from the thick film electrode portion 15c toward one side in the channel length direction. The LDD region 12cd is provided so as to overlap the portion of the thin film electrode portion 14c protruding from the thick film electrode portion 15c of the first gate electrode G. Thus, the LDD region 12cd is formed in a self-aligned manner so as to overlap the portion of the thin film electrode portion 14c protruding from the thick film electrode portion 15c by doping the first semiconductor layer 12c with impurity ions using the first gate electrode G as a mask. Further, in the second TFT 9B, the lower conductive layer 14b formed of the first metal film having a relatively small thickness is provided on the resin substrate 10 side of the second semiconductor layer 17a so as to overlap the second channel region 17ac, so that the incidence of light on the second channel region 17ac can be suppressed while suppressing the deterioration of the characteristics of the second TFT 9B due to a covering property of the first interlayer insulating film 16. When the lower conductive layer 14b is formed of the second metal film having a relatively large thickness, the covering property of the first interlayer insulating film 16 covering the lower conductive layer 14b is deteriorated, so that the characteristics of the second TFT 9B may be deteriorated. As described above, the first gate electrode G has the two layer layered structure of the thin film electrode portion 14c and the thick film electrode portion 15c, so that the LDD region 12cd for stabilizing the characteristics of the first TFT 9A is formed in the first semiconductor layer 12c of the first TFT 9A, and the lower conductive layer 14b for suppressing the incidence of light on the second channel region 17ac is formed on the resin substrate 10 side of the second TFT 9B. Thus, in the organic EL display device 50c having the hybrid structure, the characteristics of the first TFT 9A using the polysilicon semiconductor can be stabilized and the deterioration of the characteristics of the second TFT 9B using the oxide semiconductor due to the light incidence can be suppressed, as efficiently as possible.

According to the organic EL display device 50c of the present embodiment, the first TFT 9A is provided to constitute the drive TFT 9d. Here, in the first TFT 9A, as described above, the electric field concentration in the second conductor region 12cb can be relaxed by the arrangement of the LDD region 12cd, so that, in the output characteristics of the drive TFT 9d, high saturation performance with stable current change with respect to an applied voltage can be obtained, and the occurrence of luminance unevenness, image sticking, and the like can be suppressed.

According to the organic EL display device 50c of the present embodiment, the LDD region 12cd is provided between the first channel region 12cc and the second conductor region 12cb in the first semiconductor layer 12c of the first TFT 9A, so that an off current of the first TFT 9A can be reduced.

According to the organic EL display device 50c of the present embodiment, in the second TFT 9B, the lower conductive layer 14b is provided on the resin substrate 10 side of the second semiconductor layer 17a so as to overlap the second channel region 17ac, so that diffusion of impurity ions included in the resin substrate 10 into the second channel region 17ac can be suppressed, and deterioration of the characteristics of the second TFT 9B can be suppressed.

### Fourth Embodiment

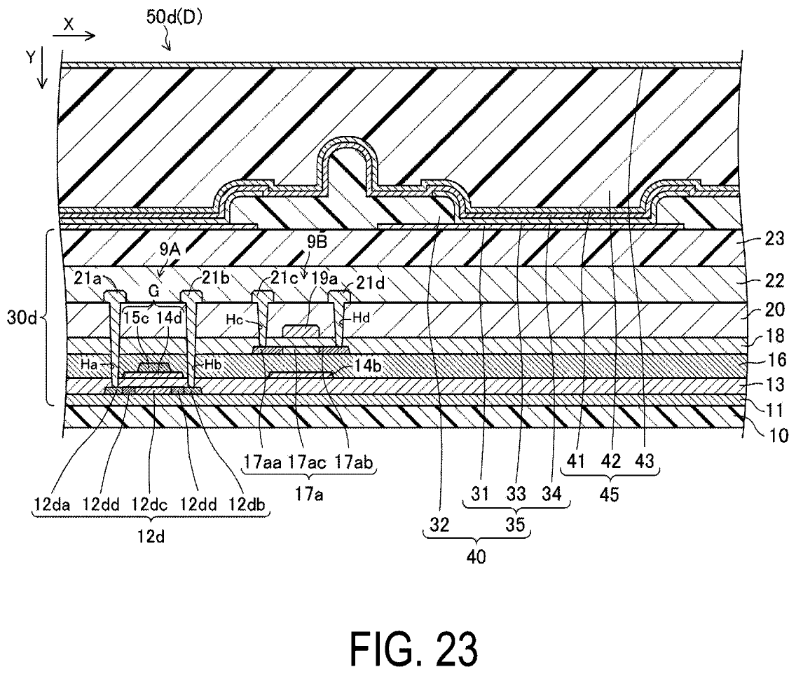

FIG. 23 illustrates a fourth embodiment of the display device according to the disclosure. Here, FIG. 23 is a cross-sectional view of a display region D of an organic EL display device 50d according to the present embodiment, and is a view corresponding to FIG. 3 described in the above-described first embodiment.

In the third embodiment described above, the organic EL display device 50c is exemplified in which the first semiconductor layer 12c including one LDD region 12cd is provided. However, in the present embodiment, the organic EL display device 50d provided with a first semiconductor 12d including two LDD regions 12dd is exemplified.

As with the organic EL display device 50a of the first embodiment described above, the organic EL display device 50d includes, for example, the display region D provided in a rectangular shape and a frame region F provided in a periphery of the display region D.

As illustrated in FIG. 23, the organic EL display device 50d includes the resin substrate 10, the TFT layer 30d provided on the resin substrate 10, the organic EL element layer 40 provided on the TFT layer 30d, and the sealing film 45 provided on the organic EL element layer 40.

As illustrated in FIG. 23, as with the TFT layer 30a of the first embodiment described above, the TFT layer 30d includes the base coat film 11 provided on the resin substrate 10, four first TFTs 9A, three second TFTs 9B, and one capacitor 9h (see FIG. 4) provided on the base coat film 11 for each subpixel P, and the protective insulating film 22 and the flattening film 23 sequentially provided on all of the first TFT 9A, the second TFT 9B, and the capacitor 9h. Here, as with the TFT layer 30a of the first embodiment described above, the TFT layer 30d is provided with the plurality of gate lines, the plurality of light emission control lines, the plurality of second initialization power source lines 19i, the plurality of source lines 21f, and the plurality of power source lines 21g. In the TFT layer 30d, the plurality of gate lines and the plurality of light emission control lines are formed not of the first metal film having a relatively small thickness but of the second metal film having a relatively large thickness.

In the TFT layer 30d, as with the TFT layer 30a of the first embodiment described above, the base coat film 11, the first semiconductor film 12, the first gate insulating film 13, the first metal film, the second metal film, the first interlayer insulating film 16, the second semiconductor film 17, the second gate insulating film 18, the third metal film 19, the second interlayer insulating film 20, the fourth metal film 21, the protective insulating film 22, and the flattening film 23 are sequentially layered on the resin substrate 10.

As illustrated in FIG. 23, the first TFT 9A includes the first semiconductor layer 12d provided on the base coat film 11, the first gate insulating film 13 provided on the first semiconductor layer 12d, the first gate electrode G provided on the first gate insulating film 13, the first interlayer insulating film 16, the second gate insulating film 18, and the second interlayer insulating film 20 sequentially provided so as to cover the first gate electrode G, and the first terminal electrode 21a and the second terminal electrode 21b provided on the second interlayer insulating film 20 so as to be separated from each other.

The first semiconductor layer 12d is formed of the first semiconductor film 12 made of, for example, polysilicon such as LTPS, and, as illustrated in FIG. 23, includes the first conductor region 12da and the second conductor region 12db defined so as to be separated from each other, the first channel region 12dc defined between the first conductor region 12da and the second conductor region 12db, and a pair of the LDD regions 12dd respectively provided between the first conductor region 12da and the first channel region 12dc and between the second conductor region 12db and the first channel region 12dc. Here, the LDD region 12dd is a low-concentration impurity region having an impurity concentration lower than those of the first conductor region 12da and the second conductor region 12db, and, as illustrated in FIG. 23, is provided so as to overlap a portion of a thin film electrode portion 14d protruding from the thick film electrode portion 15c. In the first semiconductor layer 12d, the structure in which the LDD regions 12dd are respectively provided on the first conductor region 12da side and the second conductor region 12db side of the first channel region 12dc is effective for a TFT through which bi-directional currents flows, such as a TFT for driving a subpixel of a liquid crystal display device.

The first gate electrode G is formed of a layered film of a first metal film having a relatively thick film thickness and a second metal film having a relatively thin film thickness, as illustrated in FIG. 23, is provided so as to overlap the first channel region 12dc of the first semiconductor layer 12d, and is configured to control conduction between the first conductor region 12da and the second conductor region 12db of the first semiconductor layer 12d. As illustrated in FIG. 23, the first gate electrode G includes the thick film electrode portion 15c formed of the second metal film, and the thin film electrode portion 14d formed of the first metal film so as to overlap the thick film electrode portion 15c and protrude from the thick film electrode portion 15c toward one side and the other side in the channel length direction (X direction in the drawing). Here, as illustrated in FIG. 23, the thin film electrode portion 14d is provided so as to cover both end portions of the thick film electrode portion 15c in the channel length direction (the X direction in the drawing) in a cross-sectional view.

In the organic EL display device 50d having the configuration described above, as with the organic EL display device 50a of the first embodiment described above, in each subpixel P, the organic EL element 35 emits light at luminance corresponding to a drive current to perform the image display.

The organic EL display device 50d of the present embodiment can be manufactured by changing the pattern shape when patterning the first metal film in the TFT layer forming step of the method for manufacturing the organic EL display device 50c of the third embodiment.

As described above, according to the organic EL display device 50d of the present embodiment, in the first TFT 9A, the LDD regions 12dd having an impurity concentration lower than those of the first conductor region 12da and the second conductor region 12db are respectively provided between the first channel region 12dc and the first conductor region 12da, and between the first channel region 12dc and the second conductor region 12db in the first semiconductor layer 12d, so that the electric field concentration in the first conductor region 12da and the second conductor region 12db can be relaxed, and the characteristics of the first transistor TFT 9A can be stabilized. Here, the first gate electrode G of the first TFT 9A includes the thick film electrode portion 15c formed of the second metal film having a relatively large thickness and the thin film electrode portion 14d formed of the first metal film having a relatively small thickness so as to overlap the thick film electrode portion 15c and protrude from the thick film electrode portion 15c toward both sides in the channel length direction. The LDD region 12dd is provided so as to overlap the portion of the thin film electrode portion 14d protruding from the thick film electrode portion 15c of the first gate electrode G. Thus, the LDD region 12dd is formed in a self-aligned manner so as to overlap the portion of the thin film electrode portion 14d protruding from the thick film electrode portion 15c by doping the first semiconductor layer 12d with impurity ions using the first gate electrode G as a mask. Further, in the second TFT 9B, the lower conductive layer 14b formed of the first metal film having a relatively small thickness is provided on the resin substrate 10 side of the second semiconductor layer 17a so as to overlap the second channel region 17ac, so that the incidence of light on the second channel region 17ac can be suppressed while suppressing the deterioration of the characteristics of the second TFT 9B due to a covering property of the first interlayer insulating film 16. When the lower conductive layer 14b is formed of the second metal film having a relatively large thickness, the covering property of the first interlayer insulating film 16 covering the lower conductive layer 14b is deteriorated, so that the characteristics of the second TFT 9B may be deteriorated. As described above, the first gate electrode G has the two layer layered structure of the thin film electrode portion 14d and the thick film electrode portion 15c, so that the LDD region 12dd for stabilizing the characteristics of the first TFT 9A is formed in the first semiconductor layer 12d of the first TFT 9A, and the lower conductive layer 14b for suppressing the incidence of light on the second channel region 17ac is formed on the resin substrate 10 side of the second TFT 9B. Thus, in the organic EL display device 50d having the hybrid structure, the characteristics of the first TFT 9A using the polysilicon semiconductor can be stabilized and the deterioration of the characteristics of the second TFT 9B using the oxide semiconductor due to the light incidence can be suppressed, as efficiently as possible.

According to the organic EL display device 50d of the present embodiment, the first TFT 9A is provided to constitute the drive TFT 9d. Here, in the first TFT 9A, as described above, the electric field concentration in the second conductor region 12db can be relaxed by the arrangement of the LDD region 12dd, so that, in the output characteristics of the drive TFT 9d, high saturation performance with stable current change with respect to an applied voltage can be obtained, and the occurrence of luminance unevenness, image sticking, and the like can be suppressed.

According to the organic EL display device 50d of the present embodiment, the LDD region 12dd is provided between the first channel region 12dc and the second conductor region 12db in the first semiconductor layer 12d of the first TFT 9A, so that an off current of the first TFT 9A can be reduced.

According to the organic EL display device 50d of the present embodiment, in the second TFT 9B, the lower conductive layer 14b is provided on the resin substrate 10 side of the second semiconductor layer 17a so as to overlap the second channel region 17ac, so that diffusion of impurity ions included in the resin substrate 10 into the second channel region 17ac can be suppressed, and deterioration of the characteristics of the second TFT 9B can be suppressed.

### OTHER EMBODIMENTS

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure is also applicable to an organic EL display device in which the layered structure of the organic EL layer is reversed with the first electrode being a cathode electrode and the second electrode being an anode electrode.

In each of the embodiments described above, the organic EL display device is exemplified as a display device. The disclosure can also be applied to a display device including a plurality of light-emitting elements driven by a current, for example, to a display device including quantum dot light-emitting diodes (QLEDs), which are a light-emitting element using a quantum dot-containing layer.

### INDUSTRIAL APPLICABILITY

As described above, the disclosure is useful for a flexible display device.

1. A display device comprising:
a base substrate; and
a thin film transistor layer provided on the base substrate, the thin film transistor layer including a first semiconductor film made of polysilicon, a first inorganic insulating film, a first metal film, a second metal film, a second inorganic insulating film, a second semiconductor film made of an oxide semiconductor, a third inorganic insulating film, and a third metal film sequentially layered,
wherein the thin film transistor layer is provided with a first thin film transistor including a first semiconductor layer formed of the first semiconductor film and a second thin film transistor including a second semiconductor layer formed of the second semiconductor film for each subpixel constituting a display region,
the first thin film transistor includes the first semiconductor layer including a first conductor region and a second conductor region defined to be separated from each other and a first channel region defined between the first conductor region and the second conductor region, and a first gate electrode provided on the first semiconductor layer via the first inorganic insulating film and formed of a layered film of the first metal film and the second metal film,
the second thin film transistor includes the second semiconductor layer including a third conductor region and a fourth conductor region defined to be separated from each other and a second channel region defined between the third conductor region and the fourth conductor region, and a second gate electrode provided on the second semiconductor layer via the third inorganic insulating film and formed of the third metal film,
the first gate electrode includes a thick film electrode portion formed of a thicker one of the first metal film and the second metal film, and a thin film electrode portion formed of a thinner one of the first metal film and the second metal film in such a manner as to overlap the thick film electrode portion and protrude from the thick film electrode portion toward at least one side in a channel length direction,
the first semiconductor layer is provided with a low-concentration impurity region having an impurity concentration lower than an impurity concentration of each of the first conductor region and the second conductor region in such a manner as to overlap a portion of the thin film electrode portion protruding from the thick film electrode portion, and
a lower conductive layer formed of a thinner one of the first metal film and the second metal film is provided on the base substrate side of the second semiconductor layer in such a manner as to overlap the second channel region.

2. The display device according to claim 1,
wherein the thick film electrode portion is formed of the first metal film, and
the thin film electrode portion is formed of the second metal film and is provided covering one end portion of the thick film electrode portion in a channel length direction.

3. The display device according to claim 1,
wherein the thick film electrode portion is formed of the first metal film, and
the thin film electrode portion is formed of the second metal film and is provided to cover both end portions of the thick film electrode portion in a channel length direction.

4. The display device according to claim 1,
wherein the thick film electrode portion is formed of the second metal film, and
the thin film electrode portion is formed of the first metal film and is provided protruding from the thick film electrode portion toward one side in a channel length direction.

5. The display device according to claim 1,
wherein the thick film electrode portion is formed of the second metal film, and
the thin film electrode portion is formed of the first metal film and is provided protruding from the thick film electrode portion toward both sides in a channel length direction.

6. The display device according to claim 4,
wherein the first metal film and the second metal film are made of materials different from each other.

7. The display device according to claim 1,
wherein the thin film transistor layer includes a fourth inorganic insulating film and a fourth metal film sequentially layered on the third metal film,
the first thin film transistor includes a first terminal electrode and a second terminal electrode separated from each other and formed of the fourth metal film, the first terminal electrode and the second terminal electrode being electrically connected to the first conductor region and the second conductor region, respectively, and
the second thin film transistor includes a third terminal electrode and a fourth terminal electrode separated from each other and formed of the fourth metal film, the third terminal electrode and the fourth terminal electrode being electrically connected to the third conductor region and the fourth conductor region, respectively.

8. The display device according to claim 1,
wherein the base substrate is made of an organic resin material.

9. The display device according to claim 8,
wherein a base coat film is provided on the base substrate, and
the first semiconductor layer is provided on the base coat film.

10. The display device according to claim 1, further comprising:
a light-emitting element layer provided on the thin film transistor layer and including a plurality of light-emitting elements being arrayed; and
a sealing film provided on the light-emitting element layer.

11. The display device according to claim 10,
wherein each of the plurality of light-emitting elements is an organic electroluminescence element.

12. The display device according to claim 10,
wherein the first thin film transistor is provided to configure a drive thin film transistor configured to control a current of each of the plurality of light-emitting elements.
